(19) United States
(12) Patent Application Publication
(10) Pub. No.: US 2012/0288983 A1
(43) Pub. Date: Nov. 15, 2012

(54) METHOD FOR MANUFACTURING DYE SENSITIZED SOLAR CELL MODULE

(75) Inventors: Moo Jung Chu, Daejeon (KR); Ju Mi Kim, Daejeon (KR); Yong Sung Eom, Daejeon (KR); Ah Ram Jeon, Daejeon (KR); Jong Tae Moon, Chungcheongnam-do (KR)

(73) Assignee: ELECTRONICS AND TELECOMMUNICATIONS RESEARCH INSTITUTE, Daejeon (KR)

(21) Appl. No.: 13/459,560

(22) Filed: Apr. 30, 2012

(30) Foreign Application Priority Data
May 11, 2011 (KR) 10-2011-0043857

(51) Int. Cl. H01L 31/18

(52) U.S. Cl. 438/73; 257/E31.11

(57) ABSTRACT

Disclosed is a method for manufacturing a dye sensitized solar cell module. The method includes putting at least one or more heating-wires on an upper portion of an electrode of each solar cell sub-module; applying a metal paste on the upper portion of the electrode including at least one or more heating-wires; and heating and curing the metal paste by after overlapping the electrodes of a plurality of solar cell sub-modules each other, allowing a current to flow to at least one or more heating-wires.

### CROSS-REFERENCE TO RELATED APPLICATIONS

This application is based on and claims priority from Korean Patent Application No. 10-2011-0043857, filed on May 11, 2011, with the Korean Intellectual Property Office, the disclosure of which is incorporated herein in its entirety by reference.

### TECHNICAL FIELD

The present disclosure relates to a dye sensitized solar cell module, and more particularly, to a method for manufacturing a dye sensitized solar cell module, which joins electrodes of a plurality of solar cell sub-modules with each other by using a metal paste having excellent electric conductivity, durability and mechanical strength.

### BACKGROUND

A solar cell module is a device producing electric energy by absorbing rays including solar rays and converting light energy into electric energy.

FIG. 1 is a view illustrating a basic structure of a unit solar cell.

Referring to FIG. 1, the solar cell is provided with an anode glass substrate 110 on which an anode electrode 112 is applied, a cathode glass substrate 120 on which a cathode electrode 122 is applied, a catalyst layer 114 finely applied on an upper portion of the anode electrode 112 in a level of a thin film of a single atomic layer, a TiO₂ layer 124 attached to a lower portion of the cathode electrode 122 in a state where the dye is adsorbed, and a sealing material 140 maintaining an interval so that the anode electrode 112 and the cathode electrode 122 do not contact with each other and sealing an electrolyte 130 therein.

FIG. 2 is a view illustrating a general structure of solar cell sub-modules integrated on a single substrate.

Referring to FIG. 2, the cathode electrode 122 of the solar cell constitutes an electric series connection circuit by being connected to the anode electrode 112 of the solar cell adjacent thereto through a partition wall 150 having a sealing material function and an electric insulation function between the solar cells. One solar cell sub-module is constituted by integrating several unit solar cells.

FIG. 3 is a view explaining a method for manufacturing a dye sensitized solar cell module by linking a plurality of solar cell sub-modules to each other.

Referring to FIG. 3, an anode glass substrate 110 and a cathode glass substrate 120 protrude at both ends of the solar cell sub-module, and the anode electrode 112 and the cathode electrode 122 are applied on the upper portion of the protruding anode glass substrate 110 and the lower portion of the cathode glass substrate 120 respectively.

The protruding anode electrode 112 and cathode electrode 122 are linked by overlapping, and are bonded by using a conductive adhesive agent 310 in order to improve the electric property. In this case, a matter obtained by linking the solar cell sub-modules in series by the required number is called a string, and the dye sensitized solar cell module is manufactured by connecting the strings in parallel by the required number.

FIG. 4 is a view explaining a manner generally used in electric linking between the solar cell sub-modules.

Referring to FIG. 4, if an end of a metal tape 410 is linked to an end of the protruding cathode electrode 122 of the solar cell sub-module by means such as soldering and another end of the metal tape 410 is linked to the protruding anode electrode 112 of the solar cell sub-module to be linked, electric series linking may be constituted.

This known manner is advantageous in that electric linking can be performed by only a simple manual operation and the used material is relatively low-priced.

However, in the known method of electric linking between the solar cell sub-modules, an error of an appearance of the dye sensitized solar cell module is increased because a position error between the solar cell sub-modules connected to each other can be large, an additional structure for support needs to be used because it is difficult to ensure strength and durability of a linking portion, and consistency of quality is reduced because the solar cell sub-modules are individually soldered, and the known method is not suitable to mass production by automation.

As a method for solving the aforementioned problems, if the electrodes of the solar cell sub-modules are joined with each other by using the metal paste having excellent electric conductivity, durability and mechanical strength instead of the conductive adhesive agent, a dye sensitized solar cell module having excellent performance and high reliability can be manufactured.

The metal paste is a kind of conductive adhesive agent cured by heating, and obtained by mixing a thermosetting resin with metal powder and other additives. The metal paste has no conductivity or very low conductivity before being cured, and has very low electric resistance and high attachment strength and hardness after being cured by heating.

Accordingly, if the metal paste is applied on the electrode of the solar cell sub-module, linked thereto, and then cured by heating in a state where the resulting electrode is fixed so as not to move, the linking portion is mechanically fixed and electric connection is accomplished.

Since the dye sensitized solar cell module includes a liquid electrolyte, performance thereof may be degraded or completely destroyed at high temperature. Accordingly, only the corresponding element needs to be selectively heated so as to prevent the dye sensitized solar cell module from being damaged while the electrode element is heated at high temperatures to cure a metal paste 510. A laser heating manner of FIG. 5 and a high frequency induction heating manner of FIG. 6 may be used as the local heating manner, and local cooling may also be used, if necessary, in order to prevent an increase of the temperature due to conduction of heat.

However, since the electrode of the known solar cell sub-module has a narrow and long shape, there are disadvantages in that a required time is relatively long and a cost of used equipment is high for processes of the laser and induction heating manners.

### SUMMARY

In the case where electrodes of a solar cell sub-module are linked to each other to constitute a dye sensitized solar cell module, a current of several ampere (A) to several tens ampere (A) needs to flow through a linking portion, a resistance value of the linking portion needs to be low so as to reduce a loss of electric power, and mechanical strength and durability of the linking portion need to be sufficient in order to ensure reliability of the dye sensitized solar cell module in use over a long period of time.

It is required that a manufacturing process is simple, automation is easy, the process is suitable for mass production, and economic efficiency is increased by using a low-priced material.

The present disclosure has been made in an effort to provide a method for manufacturing a dye sensitized solar cell module having excellent performance and high reliability by joining electrodes of solar cell sub-modules with each other using a metal paste.

An exemplary embodiment of the present disclosure provides a method for manufacturing a dye sensitized solar cell module, including: putting at least one or more heating-wires on an upper portion of an electrode of each solar cell sub-module; applying a metal paste on the upper portion of the electrode including at least one or more heating-wires; and heating and curing the metal paste by after overlapping the electrodes of a plurality of solar cell sub-modules with each other, allowing a current to flow to at least one or more heating-wires.

According to the exemplary embodiment of the present disclosure, there are effects that linking and fixing between solar cell sub-modules are made easy and mechanical strength, electric property and durability of a dye sensitized solar cell module are improved by providing a method for manufacturing a dye sensitized solar cell module, which joins electrodes of a plurality of solar cell sub-modules with each other using a metal paste.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating a basic structure of a unit solar cell.

FIG. 2 is a view illustrating a general structure of solar cell sub-modules integrated on a single substrate.

FIG. 3 is a view explaining a method for manufacturing a dye sensitized solar cell module by linking a plurality of solar cell sub-modules to each other.

FIG. 4 is a view explaining a manner generally used in electric linking between the solar cell sub-modules.

FIG. 5 is a view illustrating a method for heating a metal paste through laser heating in a known method for manufacturing a dye sensitized solar cell module.

FIG. 6 is a view illustrating a method for heating a metal paste through high frequency induction heating in the known method for manufacturing the dye sensitized solar cell module.

FIG. 7 is a view explaining a method for manufacturing a dye sensitized solar cell module according to a first exemplary embodiment of the present disclosure.

FIG. 8 is a view explaining a method for manufacturing a dye sensitized solar cell module according to a second exemplary embodiment of the present disclosure.

FIG. 9 is a view explaining a method for manufacturing a dye sensitized solar cell module according to a third exemplary embodiment of the present disclosure.

FIG. 10 is a view explaining a method for manufacturing a dye sensitized solar cell module according to a fourth exemplary embodiment of the present disclosure.

FIG. 11 is a view illustrating various shapes of heating-wires for uniformly heating the metal paste.

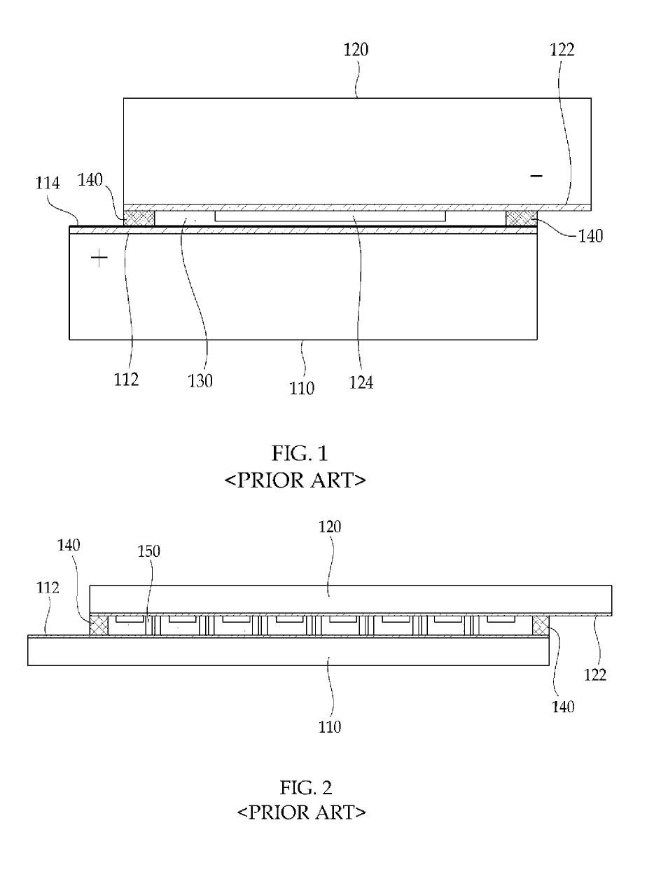

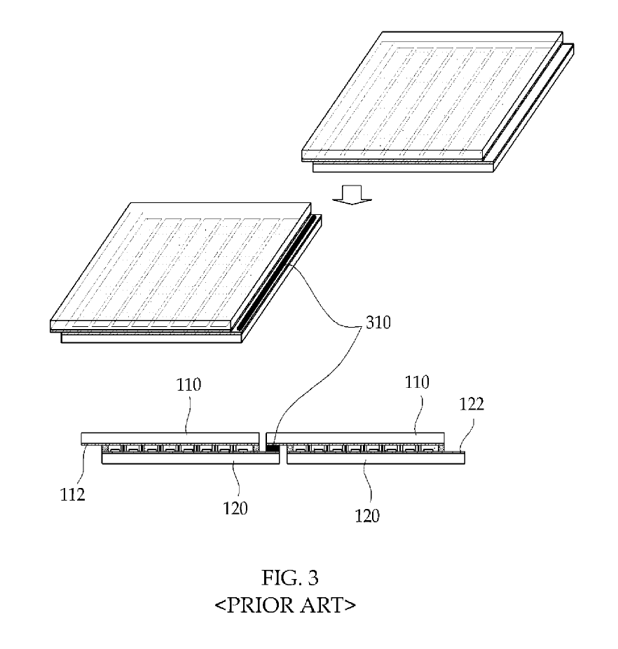

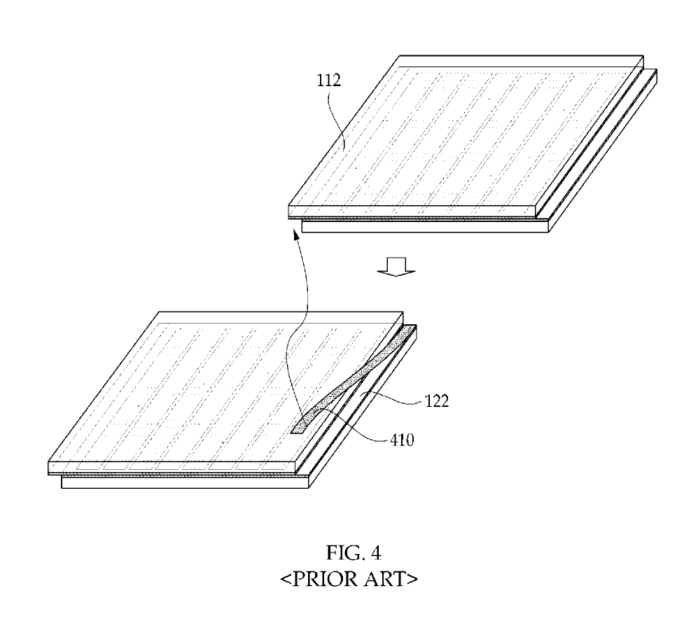

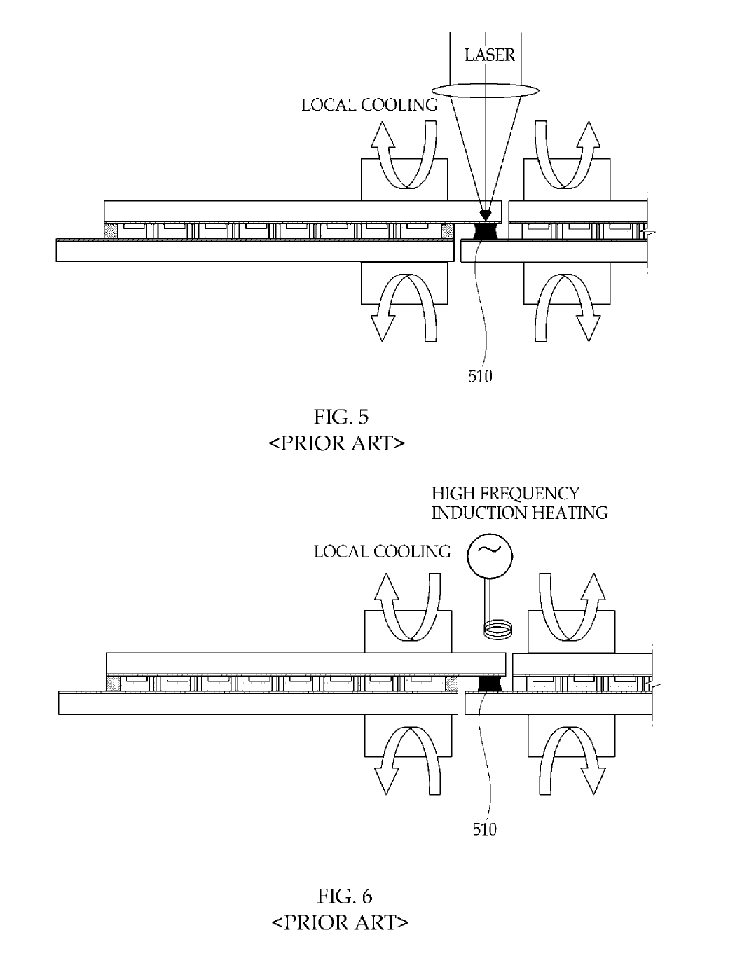

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Hereinafter, an exemplary embodiment of the present disclosure will be described in detail with reference to the accompanying drawings. In the description of the present disclosure, the detailed descriptions of known related constitutions or functions thereof may be omitted if they make the gist of the present disclosure unclear.

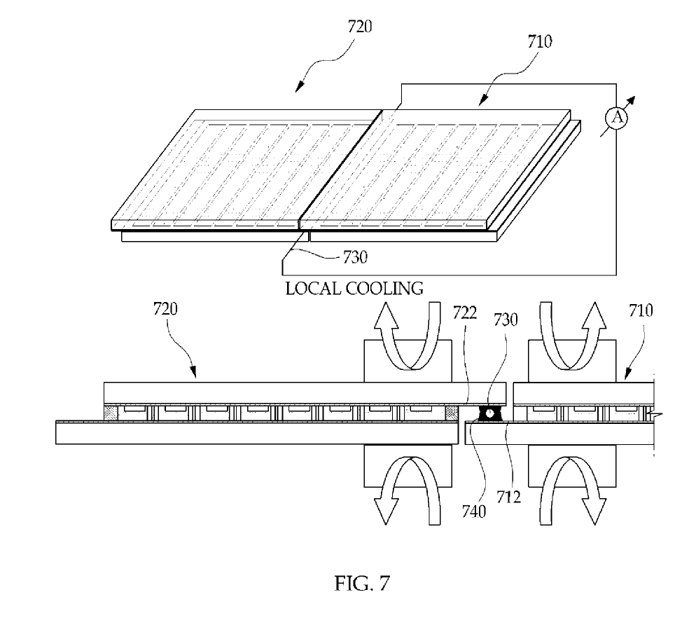

FIG. 7 is a view explaining a method for manufacturing a dye sensitized solar cell module according to a first exemplary embodiment of the present disclosure.

Referring to FIG. 7, a heating-wire 730 of metal is put on an upper portion of an anode electrode 712 of a first solar cell sub-module 710, and a metal paste 740 is applied to have a thickness that is the same as or larger than the thickness of the heating-wire 730 on the upper portion of the anode electrode 712 on which the heating-wire 730 is put. A cathode electrode 722 of a second solar cell sub-module 720 to be linked is stacked on the anode electrode 712 of the first solar cell sub-module 710 on which the metal paste 740 is applied, the metal paste 740 is heated by generating heat by allowing a current to flow through the heating-wire 730, and electrodes 712 and 722 are fixed by curing the heated metal paste 740. Next, the heating-wire 730 protruding from the electrodes 712 and 722 to the outside is cut.

In this case, since the electrodes 712 and 722 are conductive, a current may directly flow therethrough to perform heating, but if a large current is applied to the electrodes 712 and 722 so that heating is performed to a curing temperature of the metal paste 740, the electrode having the thin film shape may be broken and an excessively large area including an element on which the metal paste 740 is applied is heated, which is not preferable.

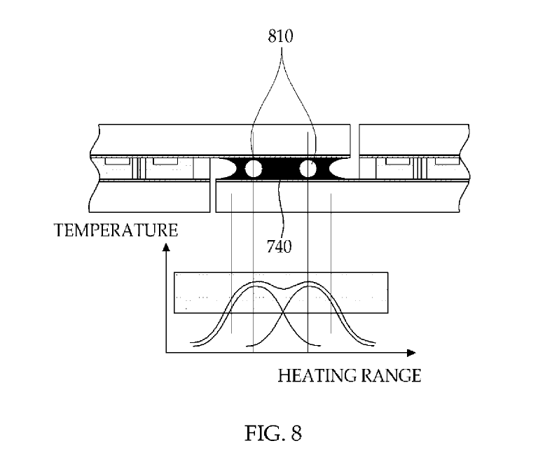

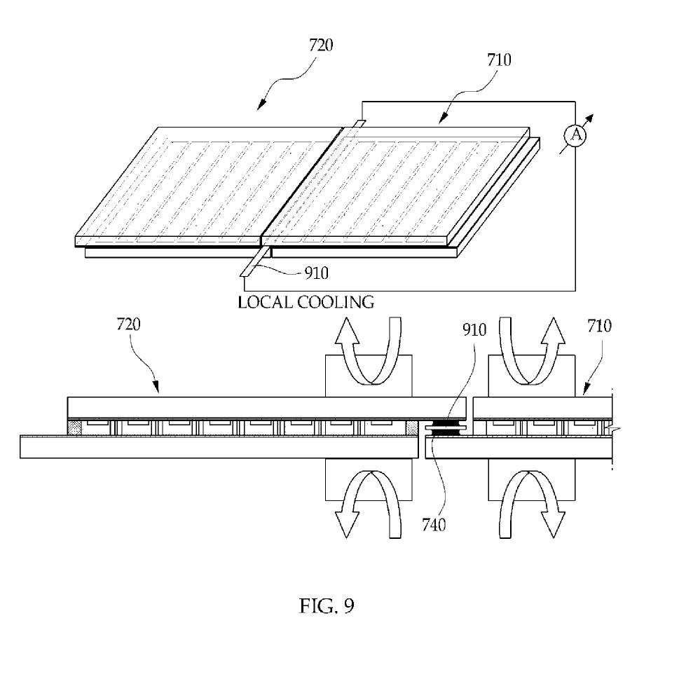

FIG. 8 is a view explaining a method for manufacturing a dye sensitized solar cell module according to a second exemplary embodiment of the present disclosure.

Referring to FIG. 8, in a second exemplary embodiment of the present disclosure, two heating-wires 810 that are parallel are used to uniformly heat the metal paste 740. For the convenience of description, even though two heating-wires 810 are described as an example in the second exemplary embodiment of the present disclosure, but the example is not limited thereto, and at least one or more heating-wires may be used according to an application area of the metal paste 740 in order to adjust an optimum curing temperature range of the metal paste 740.

FIG. 9 is a view explaining a method for manufacturing a dye sensitized solar cell module according to a third exemplary embodiment of the present disclosure.

Referring to FIG. 9, in the third exemplary embodiment of the present disclosure, a heating-wire 910 having a ribbon shape having a large width may be used to adjust the optimum curing temperature range of the metal paste 740.

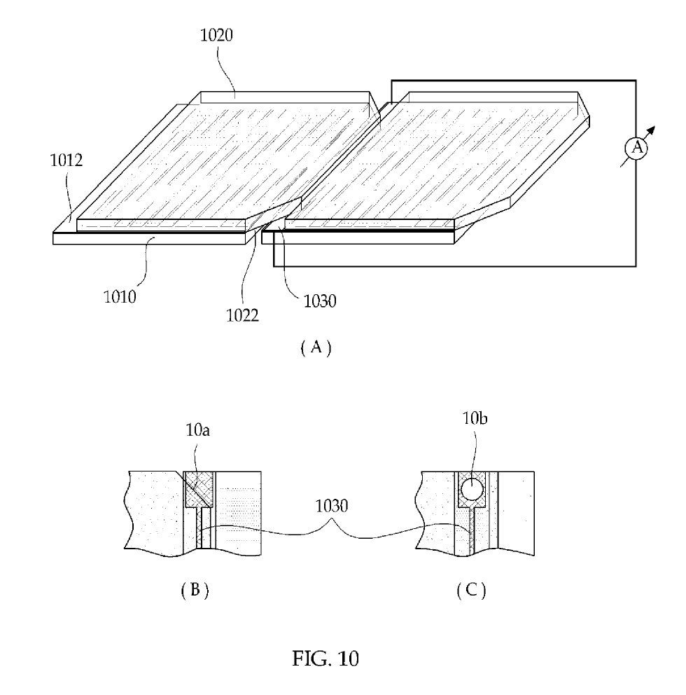

FIG. 10 is a view explaining a method for manufacturing a dye sensitized solar cell module according to a fourth exemplary embodiment of the present disclosure.

Referring to FIG. 10(A), in the fourth exemplary embodiment of the present disclosure, a heating-wire 1030 having a thin film shape is attached by molding to an anode electrode 1012 of an anode glass substrate 1010 or a cathode electrode 1022 of a cathode glass substrate 1020. As illustrated in FIGS. 7 to 9, since a process for inserting the heating-wire between the electrodes and performing heating has reduced precision and difficulty in automation, if the heating-wire 1030 having the conductive thin film shape is molded on the electrodes 1012 and 1022 in advance, a metal paste 1040 may be more easily heated and cured. Herein, the heating-wire 1030 having the conductive thin film shape may be manufactured through a method for after depositing a metal material on electrodes 1012 and 1022 in a vacuum or applying the metal paste through screen printing, performing heating and curing.

A current may be supplied to the heating-wire 1030 by cutting 10a a portion of a corner of glass substrates 1010 and 1020 as illustrated in FIG. 10(B) or piercing a hole 10b in the glass substrates 1010 and 1020 as illustrated in FIG. 10(C) in order to form an electrode linking portion for applying a current to allow the current to flow through the heating-wire 1030 having the conductive thin film shape, thus performing heating.

Meanwhile, as illustrated in FIG. 8, a resistance value and a shape of the heating-wire may be controlled in addition to the use of at least one or more heating-wires in order to uniformly heat the metal paste 1040.

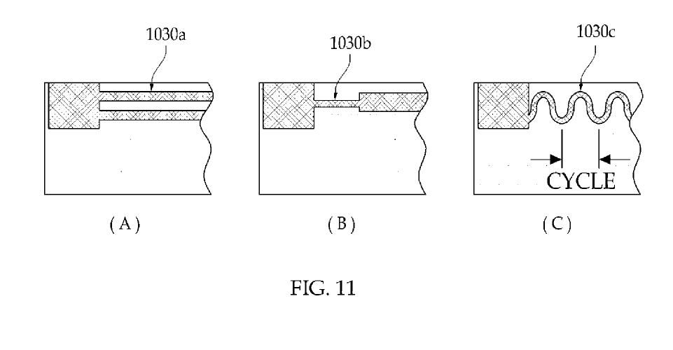

FIG. 11 is a view illustrating various shapes of heating-wires for uniformly heating the metal paste.

As illustrated in FIG. 11(A), the metal paste may be more uniformly heated by arranging at least one or more heating-wires 1110a and controlling the width of the heating-wire 1030a and an interval between the heating-wires.

As illustrated in FIG. 11(B), the metal paste may be more uniformly heated by varying the widths of the heating-wires 1030b according to an element thereof so that resistance values are made different from each other to control a caloric value.

As illustrated in FIG. 11(C), the metal paste may be more uniformly heated by constituting the heating-wire 1030c in a waveform and controlling the width and the periods of the heating-wire 1110c.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method for manufacturing a dye sensitized solar cell module, comprising:
putting at least one or more heating-wires on an upper portion of an electrode of each solar cell sub-module;
applying a metal paste on the upper portion of the electrode including at least one or more heating-wires; and
heating and curing the metal paste by after overlapping the electrodes of a plurality of solar cell sub-modules each other, allowing a current to flow to at least one or more heating-wires.

2. The method for manufacturing a dye sensitized solar cell module of claim 1, wherein at least one or more heating-wires have a ribbon shape having a large width.

3. The method for manufacturing a dye sensitized solar cell module of claim 1, wherein at least one or more heating-wires have a thin film shape and are attached to the upper portion of the electrode of each solar cell sub-module.

4. The method for manufacturing a dye sensitized solar cell module of claim 3, wherein at least one or more heating-wires are manufactured by after depositing a metal on the upper portion of the electrode of each solar cell sub-module by a physical or chemical method or applying the metal paste thereon through screen printing and curing by heating.

5. The method for manufacturing a dye sensitized solar cell module of claim 1, wherein in the heating and curing of the metal paste, the current is supplied to at least one or more heating-wires by cutting a portion of a corner of a glass substrate of the plurality of solar cell sub-modules or piercing a hole in the glass substrate.

6. The method for manufacturing a dye sensitized solar cell module of claim 1, wherein a temperature is made uniform when the metal paste is heated by controlling a number, a shape and a line width of at least one or more heating-wires.

7. The method for manufacturing a dye sensitized solar cell module of claim 1, wherein a temperature is made uniform when the metal paste is heated by differently setting widths of at least one or more heating-wires according to an element thereof.

8. The method for manufacturing a dye sensitized solar cell module of claim 1, wherein a temperature is made uniform when the metal paste is heated by constituting at least one or more heating-wires in a waveform and controlling a width and the periods of at least one or more heating-wires.
